(19) United States
(12) Patent Application Publication
(10) Pub. No.: US 2012/0298401 A1
(43) Pub. Date: Nov. 29, 2012

(54) METHOD FOR FABRICATING A THREE-DIMENSIONAL ULTRAFINE POLYMER CONDUCTING WIRE, OMNIDIRECTIONAL WIRING, AND ULTRAFINE POLYMER CONDUCTING WIRE FABRICATED USING THE METHOD

(75) Inventors: Jung Ho Je, Seoul (KR); Ji Tae Kim, Gyeonggi-do (KR); Seung Kwon Seol, Seoul (KR)

(73) Assignee: POSTECH ACADEMY-INDUSTRY FOUNDATION, Gyeongsangbuk (KR)

(21) Appl. No.: 13/574,093

(22) PCT Filed: Jan. 22, 2010
(86) PCT No.: PCT/KR2010/000412

§ 371 Date: Jul. 19, 2012

(51) Int. Cl. H01B 5/00; H01B 13/00

(52) U.S. Cl. 174/126.1; 427/58

(57) ABSTRACT

Disclosed herein is a method for fabricating a three-dimensional ultrafine conducting polymer wire having a high aspect ratio by local chemical polymerization using a micropipette. The fabricating method includes the steps of: (a) disposing a lower end of the micropipette, filled with an aqueous monomer solution corresponding to a conducting polymer, over a surface of a substrate at an alignment point at which the ultrafine conducting polymer wire is to be formed; (b) bringing the lower end of the micropipette into contact with the surface of the substrate at the alignment point; (c) drawing the micropipette away from the surface of the substrate by a predetermined distance to form a meniscus of the aqueous monomer solution between the lower end of the micropipette and the surface of the substrate; and (d) moving the micropipette in a growth direction of the ultrafine conducting polymer wire at a constant speed such that the meniscus is grown into the ultrafine conducting polymer wire having a high aspect ratio by a polymerization reaction of the meniscus with oxygen in the air.

### TECHNICAL FIELD

The present invention relates to a method of fabricating a three-dimensional ultrafine conducting polymer wire, omnidirectional wiring thereof and an ultrafine conducting polymer wire fabricated using the method, and, more particularly, to a method of fabricating a three-dimensional ultrafine conducting polymer wire (particularly, microwire or nanowire) by local chemical polymerization using a micropipette, omnidirectional wiring thereof and an ultrafine conducting polymer wire fabricated using the method.

### BACKGROUND ART

A conductive polymer (called “π-conjugated polymer”) is advantageous in that, since it has low density, it has specific conductivity (obtained by dividing conductivity by mass) higher than that of a metal, and its conductivity can be changed by doping, so that it can be advantageously used as an electroconductive material. Further, a conductive polymer is advantageous in that its workability is remarkably excellent compared to that of a metal even in mechanical and chemical aspects, and is advantageous in that it is flexible, strong, lightweight and chemically-inactive. A conductive polymer having such excellent properties can be applied for various fields of microelectronics, optics, communications, sensors, displays, life science, drug delivery systems, etc.

In order for the effective application of a conductive polymer, it is required to form and pattern the conductive polymer into a three-dimensional structure. Particularly, a wire-type three-dimensional structure becomes a basic unit in the fabrication of a complicated structure, and is widely put to practical use. Among them, a microwire, which is an ultrafine wire having a diameter of 1 to 1000 μm and made of a conducting polymer, and a nanowire, which is an ultrafine wire having a diameter of 1 to 1000 nm and made of a conducting polymer, are becoming more important day by day. The requirements for effectively using “microwire” or “nanowire” are as follows. First, a structure having a high aspect ratio must be provided, the structures must be individually fabricated at the desired positions, and the properties of the structure must be easy to modify. Finally, the process of fabricating the structure must be simple and the process cost thereof must be cheap.

Typical technologies for fabricating a conducting polymer microwire or a conducting polymer nanowire may be largely classified into lithography, template synthesis and electrospinning. In this case, lithography includes soft lithography and dip-pen lithography as well as general technologies used in a silicon process. Such inclusive lithography is advantageous in that it is possible to accurately align a microstructure or nanostructure, but it has the disadvantage of it being difficult to fabricate a three-dimensional wire having a high aspect ratio. Therefore, currently, in order to fabricate a three-dimensional wire, a template synthesis technology and electrospinning technology are being widely used. The template synthesis technology is advantageous in that a large number of wires can be fabricated at one time. In this case, the size and number of the wires is determined by the size and number of pores of a template. Further, the electrospinning technology is advantageous in that a long wire can be fabricated regardless of an aspect ratio. However, these two technologies are problematic in that it is difficult to accurately align the fabricated wire at a desired position, and thus a process for accurately aligning the fabricated wire is additionally required, and it is technically difficult to perform this work on the micrometer scale or the nanometer scale.

As described above, a conducting polymer nanowire as well as a conducting polymer microwire is a major material of nanotechnologies, but it is very difficult to accurate align and fabricate a three-dimensional wire and to control the individual characteristics thereof.

### DISCLOSURE OF INVENTION

### Technical Problem

A first object of the present invention is to provide a method of fabricating a three-dimensional ultrafine conducting polymer wire, wherein a three-dimensional ultrafine conducting polymer wire having a high aspect ratio can be simultaneously fabricated and aligned using the chemical polymerization of a monomer solution locally produced by a micropipette, and thus an additional process for this is not required, and to a three-dimensional ultrafine conducting polymer wire fabricated by the method.

A second object of the present invention is to provide a method of fabricating a wiring of a three-dimensional ultrafine polymer conducting wiring, wherein a three-dimensional ultrafine conducting polymer wire fabricated using a micropipette can be wired at a desired position in a desired direction, simultaneously with the fabrication thereof, and to a wiring of a three-dimensional ultrafine polymer conducting wiring fabricated by the method.

A third object of the present invention is to provide a method of individually controlling the physical or chemical characteristics of the fabricated three-dimensional ultrafine conducting polymer wire or wiring thereof, and to a three-dimensional ultrafine conducting polymer wire or wiring thereof fabricated by the method.

### Technical Solution

An aspect of the present invention provides a method of fabricating a three-dimensional ultrafine conducting polymer wire having a high aspect ratio by local chemical polymerization using a micropipette, including the steps of: (a) disposing a lower end of the micropipette, filled with an aqueous monomer solution corresponding to a conducting polymer, over a surface of a substrate at an alignment point at which the ultrafine conducting polymer wire is to be formed; (b) bringing the lower end of the micropipette into contact with the surface of the substrate at the alignment point; (c) drawing the micropipette away from the surface of the substrate by a predetermined distance to form a meniscus of the aqueous monomer solution between the lower end of the micropipette and the surface of the substrate; and (d) moving the micropipette in a growth direction of the ultrafine conducting polymer wire at a constant speed such that the meniscus is grown into the ultrafine conducting polymer wire having a high aspect ratio by a polymerization reaction of the meniscus with oxygen in the air.

In the method, in the step (a), the aqueous monomer solution may be a mixed solution of a pyrrole monomer and H₂SO₄.

Further, the mixed solution may include 50 g/L of a pyrrole monomer and 25 g/L of H₂SO₄.

Further, in the step (c), the predetermined distance may be set within in a range of 1 μm to 10 μm.

Further, in the step (d), the moving speed of the micropipette may be set within a range of 1 μm/sec to 3000 μm/sec.

Further, the diameter of the ultrafine wire may decrease as the moving speed of the micropipette increases.

Further, the ultrafine wire may be a microwire or a nanowire.

Further, in each of the steps (a), (b), (c) and (d), the micropipette may be adjusted on the micrometer scale by a stepping motor.

Further, 2-naphthalenesulfonic acid (2-NSA) may be added to the aqueous monomer solution to adjust the electroconductivity of the aqueous monomer solution.

Further, the ultrafine wire may be fabricated and aligned at the same time.

Another aspect of the present invention provides a method of fabricating a wiring of a three-dimensional ultrafine conducting polymer wire having a high aspect ratio from a first point to a second point by local chemical polymerization using a micropipette, including the steps of: (a) disposing a lower end of the micropipette, filled with an aqueous monomer solution corresponding to a conducting polymer, over a surface of a substrate at the first point; (b) bringing the lower end of the micropipette into contact with the surface of the substrate at the first point; (c) drawing the micropipette away from the first point on the surface of the substrate by a predetermined distance to form a meniscus of the aqueous monomer solution between the lower end of the micropipette and the first point on the surface of the substrate; (d) moving the micropipette in a growth direction of the ultrafine conducting polymer wire at a constant speed such that the meniscus is grown into the ultrafine conducting polymer wire having a length corresponding to the distance between the first point and the second point by a polymerization reaction of the meniscus with oxygen in the air; and (e) bringing the lower end of the micropipette into contact with the surface of the substrate at the second point.

In the method, in the step (a), the aqueous monomer solution may be a mixed solution of a pyrrole monomer and H₂SO₄.

Further, the mixed solution may include 50 g/L of a pyrrole monomer and 25 g/L of H₂SO₄.

Further, in the step (c), the predetermined distance may be set within in a range of 1 μm to 10 μm.

Further, in the step (d), the moving speed of the micropipette may be set within a range of 1 μm/sec to 3000 μm/sec.

Further, the diameter of the ultrafine wire may decrease as the moving speed of the micropipette increases.

Further, the ultrafine wire may be a microwire or a nanowire.

Further, in each of the steps (a), (b), (c) (d) and (e), the micropipette may be adjusted on the micrometer scale by a stepping motor.

Further, 2-naphthalenesulfonic acid (2-NSA) may be added to the aqueous monomer solution to adjust the electroconductivity of the aqueous monomer solution.

Further, the ultrafine wire may be fabricated and aligned at the same time.

### Advantageous Effects

According to the present invention, there can be obtained a method of fabricating a three-dimensional ultrafine conducting polymer wire, wherein a three-dimensional ultrafine conducting polymer wire having the desired diameter and length can be fabricated using a micropipette and simultaneously can be accurately aligned so that an additional process for this is not required, and there can be obtained a three-dimensional ultrafine conducting polymer wire fabricated by the method.

Further, according to the present invention, there can be obtained a method of fabricating a wiring of a three-dimensional ultrafine polymer conducting wire, wherein a three-dimensional ultrafine conducting polymer wire fabricated using a micropipette can be wired at a desired position in a desired direction, simultaneously with the fabrication thereof, and there can be obtained a wiring of the three-dimensional ultrafine polymer conducting wire fabricated by the method.

Further, according to the present invention, there can be obtained a method to individually control the physical or chemical characteristics of the fabricated three-dimensional ultrafine conducting polymer wire or wiring thereof, and there can be obtained a three-dimensional ultrafine conducting polymer wire or wiring thereof fabricated by the method.

That is, the present invention relates to the development of a local chemical polymerization method using a micropipette based on the fact that oxygen in the air is used as an oxidant in the polymerization of monomers of a conducting polymer. According to the present invention, the meniscus of the aqueous monomer solution, formed between a micropipette and a substrate, has an effective oxygen concentration higher than that of the area round it, so that the meniscus of the aqueous monomer solution polymerizes rapidly compared to the film formed of a conventional aqueous monomer solution, thereby forming a conduction polymer structure in a short period of time. In the present invention, the diameter of the meniscus was adjusted by adjusting the pulling speed of the micropipette, and thus the diameter of an ultrafine conducting polymer wire was effectively changed from micrometers to nanometers. Further, the physical and chemical characteristics of the ultrafine conducting polymer wire were individually realized by adding a specific material to the monomers. Comparing the present invention with other methods such as lithography and the like, a three-dimensional conducting polymer microwire or nanowire can be rapidly fabricated at low cost, and simultaneously can be aligned at all positions in all directions, and the characteristics thereof can be modified, thus presenting industrial applicability.

### DESCRIPTION OF DRAWINGS

FIG. 1 is a process view showing a technology for fabricating a three-dimensional ultrafine conducting polymer wire (preferably, microwire or nanowire) having a high aspect ratio using a micropipette local chemical polymerization method and simultaneously aligning the three-dimensional ultrafine conducting polymer wire.

FIG. 2a is a schematic view showing a polypyrrole wire formed when a micropipette having a radius of 5 μm and filled with an aqueous pyrrole solution was drawn away from a substrate by 2.5 μm at 0.7-second intervals, wherein the schematic view was fabricated based on real time X-ray imaging. Here, the radius of the polypyrrole wire is 3.5 μm which is smaller than that of the micropipette.

FIG. 2b is a schematic view showing a polypyrrole wire formed when a micropipette having a radius of 5 μm and filled with an aqueous pyrrole solution was drawn away from a substrate by 2.5 μm at 1.0-second intervals, wherein the schematic view was fabricated based on real time X-ray imaging. Here, the radius of the polypyrrole wire is 5.0 μm which is equal to that of the micropipette.

FIG. 2c is a graph showing the relationship of time interval with radius of a polypyrrole wire when a micropippete having a radius of 5 μm and filled with an aqueous pyrrole solution was drawn away from a substrate by 2.5 μm. Here, the radius of the polypyrrole wire increases with an increase in the time interval, and reaches the radius of the micropipette when the time interval is 1.0 second, and is then maintained constant. The minimum time interval for which wire radius/pipette radius=1 is defined as “the polymerization point”.

FIG. 2d is a graph showing the relationship of the radius of the micropipette with the polymerization point. From FIG. 2d, it can be seen that the polymerization point decreases as the radius of the micropipette decreases.

FIG. 3a is a schematic view showing the phenomenon of the radius of a polypyrrole wire decreasing alongside an increase in the speed at which the micropipette is drawn away from a substrate, wherein the schematic view was fabricated based on real time X-ray imaging.

FIG. 3b is a graph showing the relationship of the speed at which the micropipette is drawn away from the substrate with the radius of the polypyrrole wire. From FIG. 3b, it can be seen that the radius of the polypyrrole wire decreases as the speed at which the micropipette is drawn away from the substrate increases, thus obtaining a polypyrrole wire having a radius on the nanometer scale.

FIG. 4 shows the images of three-dimensional polypyrrole wire arrays fabricated by the omnidirectional drawing of the micropipette. Here, FIG. 4a shows a field emission scanning electron microscope (FE-SEM) image of a wire array having a high aspect ratio (60:1), FIG. 4b shows a field emission scanning electron microscope (FE-SEM) image of a nanowire bridge, FIG. 4c shows a field emission scanning electron microscope (FE-SEM) image of a junction structure of two nanowires, and FIG. 4d shows a field emission scanning electron microscope (FE-SEM) image of a three-dimensional arch wire array.

FIG. 5a is an I-V graph of a polymer conducting nanowire fabricated by local chemical polymerization using a micropipette. From FIG. 5a, it can be seen that an ultrafine conducting polymer wire (radius: 500 nm) connecting two gold (Au) electrodes are put into ohmic contact with the electrodes due to the fact that electric current linearly increases according to the increase of applied voltage. FIG. 5b is a graph showing the electroconductivity of the polymer conducting nanowire relative to the doping concentration of 2-naphthalenesulfonic acid added to an aqueous pyrrole solution, wherein the electroconductivity of the polymer conducting nanowire increases as the doping concentration of 2-naphthalenesulfonic acid increases.

FIG. 6 is a process view showing a technology for fabricating a wiring of the three-dimensional ultrafine conducting polymer wire (preferably, microwire or nanowire) having high aspect ratio from a first point to a second point by local chemical polymerization using a micropipette.

### BEST MODE

Hereinafter, preferred embodiments of the present invention will be described in detail with reference to the accompanying drawings.

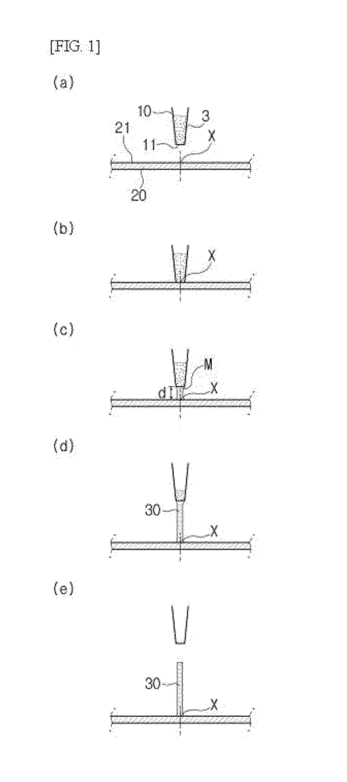

FIG. 1 is a process view showing a technology for fabricating a three-dimensional ultrafine conducting polymer wire (preferably, microwire or nanowire) having a high aspect ratio by local chemical polymerization using a micropipette. In the present invention, the core idea for fabricating an ultrafine conducting polymer wire and simultaneously aligning the ultrafine wire at a desired position is to supply an aqueous monomer solution locally.

For this, a pipette 10 having a diameter on the micrometer scale is filled with an aqueous monomer solution 3 containing the monomers of a conducting polymer, and the lower end 11 of the pipette 10 is disposed over the surface of a substrate 20 to be aligned with an alignment point (X) at which the ultrafine conducting polymer wire 30 is to be formed (refer to FIG. 1a). Subsequently, the lower end 11 of the pipette 10 is brought into contact with the surface 21 of the substrate 20 at the alignment point (X) of the ultrafine conducting polymer wire 30 (refer to FIG. 1b). Subsequently, the pipette 10 is drawn away from the surface 21 of the substrate 20 by a predetermined distance (d) to form a meniscus (M) between the surface 21 of the substrate 20 and the lower end 11 of the pipette 10 (refer to FIG. 1c). Subsequently, the pipette 10 is moved in a growth direction of the ultrafine conducting polymer wire 30 at a constant speed such that the meniscus (M) is grown into the ultrafine conducting polymer wire 30 having a high aspect ratio by the polymerization reaction of the meniscus (M) with the oxygen in the air (refer to FIG. 1d). Here, when the pipette 10 is drawn away from the meniscus (M) at constant speed, the cross-sectional area of the meniscus (M) is reduced, the meniscus (M) meets the oxygen (oxidant) in the air to polymerize, and simultaneously a solvent volatilizes from the meniscus (M) to form the ultrafine conducting polymer wire 30. In this case, the diameter of the ultrafine conducting polymer wire 30 that is formed becomes smaller than that of the meniscus (M) because the cross-sectional area of the meniscus (M) is reduced. When the pipette 10 is continuously drawn away, an ultrafine conducting polymer wire 30 having a high aspect ratio is fabricated (refer to FIG. 1e).

In the preferred embodiments of the present invention, the following experimental conditions were used.

Preferably, a glass micropipette 10 having a desired diameter was accurately worked using a pipette puller (P-97, manufactured by Sutter Instrument Corp.). Preferably, polypyrrole was used as the conducting polymer. Preferably, an aqueous monomer solution 3 for polymerization, including a pyrrole monomer (50 g/L) and H₂SO₄ (25 g/L), was used. The micropipette 10 having a diameter on the micrometer scale was filled with this aqueous monomer solution 3 and then used. Preferably, a silicon substrate deposited with platinum was used as the substrate 20. Preferably, the position of the micropipette 10 was accurately controlled by three stepping motors (not shown). The image of the fabrication method thereof was rendered in real time by phase difference X-ray imaging. The X-ray imaging test was performed at the 7B2 X-ray microscopy beamline of Pohang accelerator laboratory (PAL) in Korea. In order to research the microscopic characteristics and electrical characteristics of the prepared ultrafine structure, a field emission scanning electron microscope (FE-SEM) and an inspection meter (probe station) were used.

In the present invention, it is important to attain a predetermined diameter in the process of fabricating the conducting polymer (polypyrrole) wire 30. To achieve this, it should be understood that the reduction in the cross-sectional area of the meniscus (M) of the aqueous monomer solution 3 for the conducting polymer (polypyrrole), the meniscus (M) being formed by the contact between the micropipette 10 and the substrate 20, is related to the viscosity thereof. Actually, the rate of reduction in the cross-sectional area of the meniscus (M) decreases as the viscosity of the aqueous monomer solution 3 increases. The viscosity of the aqueous monomer solution 3 increases as the degree of polymerization of monomers increases. The polymerization of monomers is conducted because oxygen in the air serves as an oxidant, so that the polymerization thereof is related to the exposure time of the aqueous monomer solution 3 to the air. To date, a lot of research has been done into using the oxygen in the air as an oxidant at the time of forming a polypyrrole film (Gursel Sonmez et al., “Highly transmissive and conductive PXDOP films prepared by air or transition metal catalyzed chemical oxidation”, J. Mater. Chem. (2001); Chin-Lin Huang et al., “Coating of uniform inorganic particles with polymers”, J. Mater. Res. (1995)). However, research into the monomer meniscus for preparing a three-dimensional microwire or nanowire and the polymerization of the monomer meniscus has not yet been reported.

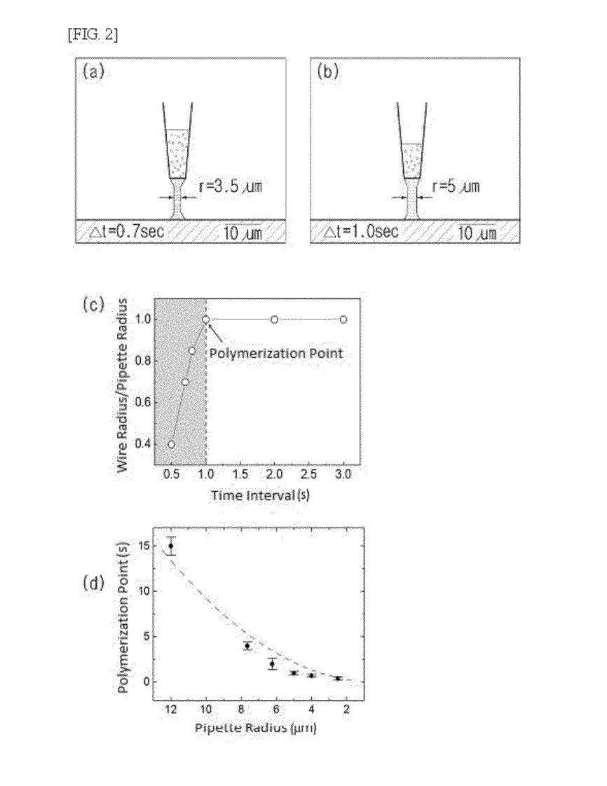

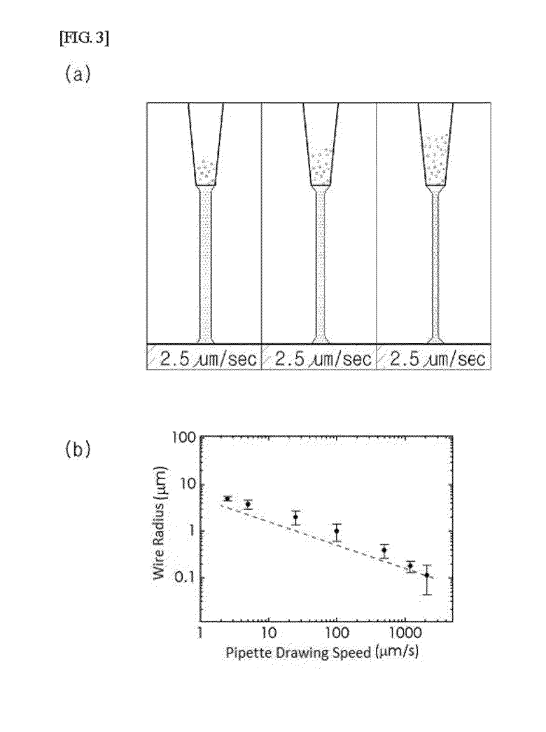

In order to understand this, the reduction in the cross-sectional area of the meniscus (M) was measured while drawing the micropipette 10 away from the meniscus by 2.5 μm at predetermined time intervals. Here, the radius of the lower end of the micropipette 10 was maintained at 5 μm. FIGS. 2a and 2b are schematic views showing polypyrrole wires formed when the time intervals are (a) 0.7 seconds and (b) 1.0 second, respectively, wherein the schematic views were fabricated based on X-ray imaging. From FIGS. 2a and 2b, it can be seen that, when the time interval was 0.7 seconds, a wire having a radius of 3.5 μm which is smaller than the radius of the micropipette was formed, whereas, when the time interval was 1.0 second, a wire having a radius of 5.0 μm which is equal to the radius of the micropipette was formed. FIG. 2c shows that the radius of the polypyrrole wire increases with the increase of the time interval, and then reaches the radius of the micropipette. Here, the minimum time interval for which the radius of the wire achieves the same radius as the micropipette is defined as the “polymerization point”. This “polymerization point” is determined by the volume of the meniscus formed in the early stage. FIG. 2d shows that the polymerization point decreases as the radius of the micropipette decreases. Thus, it can be seen from the second diffusion law that the polymerization point is determined by the concentration of oxygen that has diffused into the meniscus of the aqueous monomer solution (see a dotted line). Consequently, it is concluded that the section area of the meniscus is reduced by drawing the micropipette away from the meniscus to increase the viscosity thereof, thus forming a polypyrrole wire having a normal diameter. That is, the polypyrrole wire having a predetermined diameter is determined by the relationship of the section area of the meniscus, the diffusion time of oxygen and the viscosity of the meniscus. Therefore, it is possible to fabricate a polypyrrole wire having the desired diameter by adjusting the speed at which the micropipette is drawn away. FIG. 3a shows that the radius of a polypyrrole wire decreases from 5 μm to 1.75 μm as the speed at which the micropipette is drawn away increases from 2.5 μm/s to 25 μm/s. Moreover, FIG. 3b shows that a polypyrrole wire having a radius of 110 nm was fabricated by increasing the speed to 2100 μm/s.

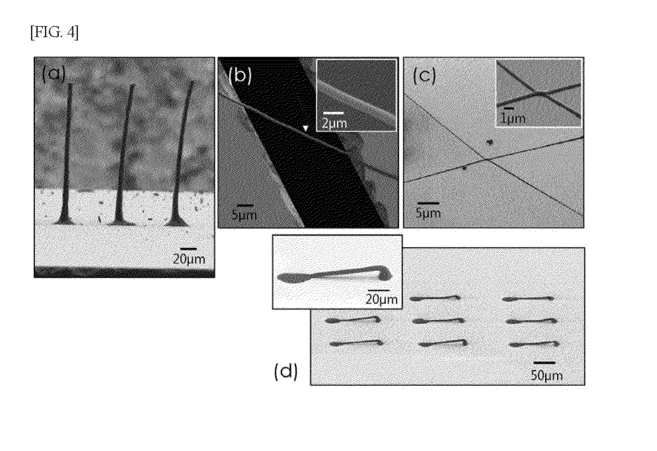

FIG. 4 shows the accurate alignment and positioning of the polypyrrole microwires and nanowires fabricated by the omnidirectional drawing of the micropipette. Here, FIG. 4a shows a polypyrrole wire array having a high aspect ratio (60:1), FIG. 4b shows a polypyrrole nanobridge (drawing speed: 500 μm/s, radius: 450 nm). Such structures are required to connect a three-dimensional conducting wire between substrates of a three-dimensional electronic circuit. FIG. 4c shows a junction structure of two nanowires (drawing speed: 1200 μm/s, radius: 200 nm), and FIG. 4d shows a three-dimensional arch wire structure (radius: 2.5 μm).

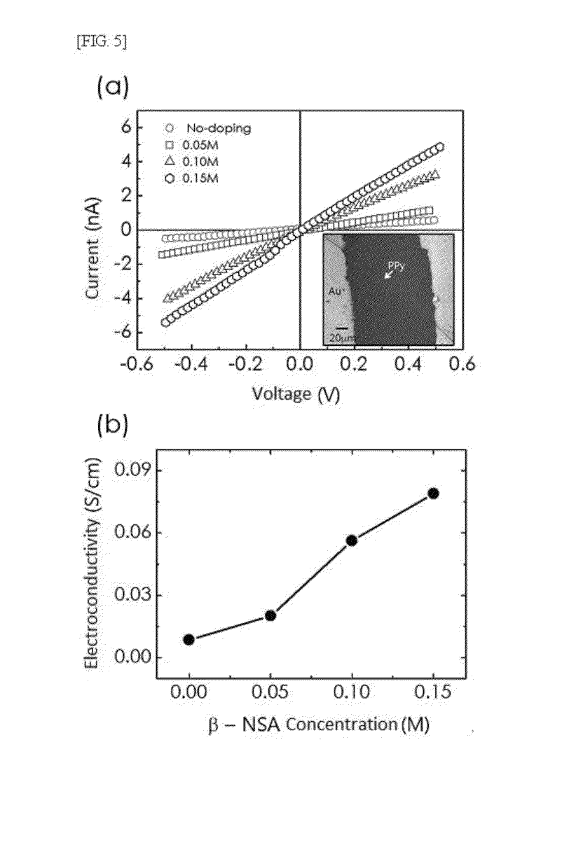

FIG. 5 shows that the electroconductivity of a nanowire can be individually adjusted by doping. The doped nanowire is necessarily used in a multi-functional circuit. For this, gold (Au) electrodes were formed on a glass substrate of an insulator, and the gold (Au) electrodes are connected by a polypyrrole nanowire. FIG. 5a is a graph showing the results of measuring the current-voltage of a polypyrrole nanowire having a radius of 500 nm, to which 2-naphthalenesulfonic acid was added to 0 M˜0.15 M, wherein the image in the graph is a field emission scanning electron microscope image showing the polypyrrole nanowire connected between the two gold (Au) electrodes. Consequently, it can be seen that the electroconductivity of the polypyrrole nanowire is adjusted in a range of 10⁻² to 10⁻¹ S/cm (refer to FIG. 5b)

The three-dimensional ultrafine conducting polymer wire 30 having a high aspect ratio, which was fabricated by the fabrication method of the present invention, can be aligned simultaneously with the fabrication thereof, so that an additional process for aligning the wire 30 is not needed.

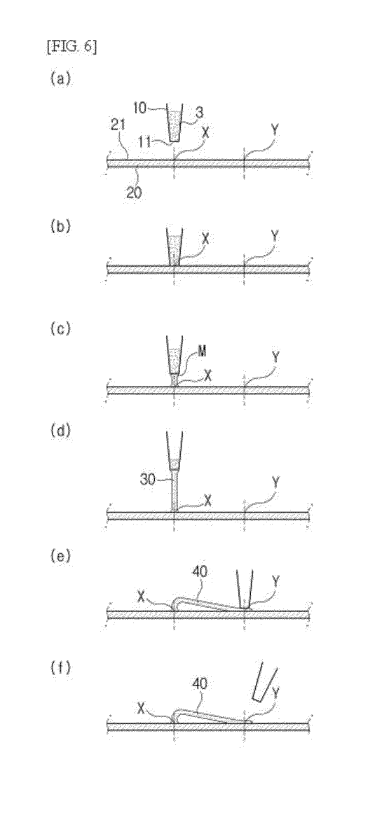

FIG. 6 is a process view showing a technology for fabricating a wiring of the three-dimensional ultrafine conducting polymer wire 40 (preferably, microwire or nanowire) having high aspect ratio from a first point (X) to a second point (Y) using local chemical polymerization using a micropipette.

First, a micropipette 10 having a diameter on the micrometer scale is filled with an aqueous monomer solution 3 containing the monomers of a conducting polymer, and the lower end 11 of the pipette 10 is disposed over the surface 21 of a substrate 20 at the first point (X) (refer to FIG. 6a).

Subsequently, the lower end 11 of the micropipette 10 is brought into contact with the surface 21 of the substrate 20 at the first point (X) (refer to FIG. 6b).

Subsequently, the micropipette 10 is drawn away from the surface 21 of the substrate 20 at the first point (X) by a predetermined distance (d) to form a meniscus (M) of the aqueous monomer solution 3 between the surface 21 of the substrate 20 at the first point (X) and the lower end 11 of the pipette 10 (refer to FIG. 6c).

Subsequently, the mircopipette 10 is moved in a growth direction of the ultrafine conducting polymer wire 30 at a constant speed such that the meniscus (M) is grown into the ultrafine conducting polymer wire 30 having a high aspect ratio by the polymerization reaction of the meniscus (M) with the oxygen in the air (refer to FIG. 6d). Here, when the micropipette 10 is drawn away from the meniscus (M) at constant speed, the cross-section area of the meniscus (M) is reduced, the meniscus (M) meets the oxygen (oxidant) in the air to polymerize, and simultaneously a solvent volatilizes from the meniscus (M) to form the ultrafine conducting polymer wire 30. In this case, the diameter of the ultrafine conducting polymer wire 30 that is formed becomes smaller than that of the meniscus (M) because the cross-sectional area of the meniscus (M) is reduced.

Finally, the low end 11 of the micropipette 10 is brought into contact with the second point (Y) on the surface 21 of the substrate 20 to fabricate a wiring 40 of the ultrafine conducting polymer wire 30 from the first point (X) to the second point (Y) (refer to FIGS. 6e and 60. The above descriptions explained in relation to the method of fabricating an ultrafine conducting polymer wire may be applied to the process of fabricating a wiring of the ultrafine conducting polymer wire.

The wiring 40 of the three-dimensional ultrafine conducting polymer wire 30 having a high aspect ratio, which was fabricated by the fabrication method thereof, can be fabricated simultaneously with the fabrication of ultrafine conducting polymer wire 30.

### DEFINITION OF TERMS

1. Conducting polymer: an electrically conductive plastic that is light and is easily processed. Examples thereof include polypyrrole, polyaniline, PEDOT and the like.

2. Ultrafine wire: a wire having diameter of 1000 μm or less.

3. Microwire: a wire having a diameter of 1 μm to 1000 μm.

4. Nanowire: a wire having a diameter of 1 nm to 1000 nm.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. A method of fabricating a three-dimensional ultrafine conducting polymer wire having a high aspect ratio by local chemical polymerization using a micropipette, comprising the steps of:
(a) disposing a lower end of the micropipette, filled with an aqueous monomer solution corresponding to a conducting polymer, over a surface of a substrate at an alignment point at which the ultrafine conducting polymer wire is to be formed;
(b) bringing the lower end of the micropipette into contact with the surface of the substrate at the alignment point;
(c) drawing the micropipette away from the surface of the substrate by a predetermined distance to form a meniscus of the aqueous monomer solution between the lower end of the micropipette and the surface of the substrate; and
(d) moving the micropipette in a growth direction of the ultrafine conducting polymer wire at a constant speed such that the meniscus is grown into the ultrafine conducting polymer wire having a high aspect ratio by a polymerization reaction of the meniscus with oxygen in the air.

2. The method of fabricating a three-dimensional ultrafine conducting polymer wire having a high aspect ratio according to claim 1, wherein, in the step (a), the aqueous monomer solution is a mixed solution of a pyrrole monomer and H₂SO₄.

3. The method of fabricating a three-dimensional ultrafine conducting polymer wire having a high aspect ratio according to claim 2, wherein the mixed solution includes 50 g/L of a pyrrole monomer and 25 g/L of H₂SO₄.

4. The method of fabricating a three-dimensional ultrafine conducting polymer wire having a high aspect ratio according to claim 1, wherein, in the step (c), the predetermined distance is set within in a range of 1 μm to 10 μm.

5. The method of fabricating a three-dimensional ultrafine conducting polymer wire having a high aspect ratio according to claim 1, wherein, in the step (d), the moving speed of the micropipette is set within a range of 1 μm/sec to 3000 μm/sec.

6. The method of fabricating a three-dimensional ultrafine conducting polymer wire having a high aspect ratio according to claim 1, wherein a diameter of the ultrafine wire decreases as the moving speed of the micropipette increases.

7. The method of fabricating a three-dimensional ultrafine conducting polymer wire having a high aspect ratio according to claim 1, wherein the ultrafine wire is a microwire or a nanowire.

8. The method of fabricating a three-dimensional ultrafine conducting polymer wire having a high aspect ratio according to claim 1, wherein, in each of the steps (a), (b), (c) and (d), the micropipette is adjusted on the micrometer scale by a stepping motor.

9. The method of fabricating a three-dimensional ultrafine conducting polymer wire having a high aspect ratio according to claim 1, wherein 2-naphthalenesulfonic acid (2-NSA) is added to the aqueous monomer solution to adjust the electroconductivity of the aqueous monomer solution.

10. A three-dimensional ultrafine conducting polymer wire having a high aspect ratio, fabricated by the method of claim 1, wherein the ultrafine wire is fabricated and aligned at the same time.

11. A method of fabricating a wiring of a three-dimensional ultrafine conducting polymer wire having a high aspect ratio from a first point to a second point by local chemical polymerization using a micropipette, comprising the steps of:
(a) disposing a lower end of the micropipette, filled with an aqueous monomer solution corresponding to a conducting polymer, over a surface of a substrate at the first point;
(b) bringing the lower end of the micropipette into contact with the surface of the substrate at the first point;
(c) drawing the micropipette away from the first point on the surface of the substrate by a predetermined distance to form a meniscus of the aqueous monomer solution between the lower end of the micropipette and the first point on the surface of the substrate;
(d) moving the micropipette in a growth direction of the ultrafine conducting polymer wire at a constant speed such that the meniscus is grown into the ultrafine conducting polymer wire having a length corresponding to the distance between the first point and the second point by a polymerization reaction of the meniscus with oxygen in the air; and
(e) bringing the lower end of the micropipette into contact with the surface of the substrate at the second point.

12. The method of fabricating a wiring of a three-dimensional ultrafine conducting polymer wire having a high aspect ratio according to claim 11, wherein, in the step (a), the aqueous monomer solution is a mixed solution of a pyrrole monomer and H₂SO₄.

13. The method of fabricating a wiring of a three-dimensional ultrafine conducting polymer wire having a high aspect ratio according to claim 12, wherein the mixed solution includes 50 g/L of a pyrrole monomer and 25 g/L of H₂SO₄.

14. The method of fabricating a wiring of a three-dimensional ultrafine conducting polymer wire having a high aspect ratio according to claim 11, wherein, in the step (c), the predetermined distance is set within a range of 1 μm to 10 μm.

15. The method of fabricating a wiring of a three-dimensional ultrafine conducting polymer wire having a high aspect ratio according to claim 11, wherein, in the step (d), the moving speed of the micropipette is set within a range of 1 μm/sec to 3000 μm/sec.

16. The method of fabricating a wiring of a three-dimensional ultrafine conducting polymer wire having a high aspect ratio according to claim 11, wherein a diameter of the ultrafine wire decreases as the moving speed of the micropipette increases.

17. The method of fabricating a wiring of a three-dimensional ultrafine conducting polymer wire having a high aspect ratio according to claim 11, wherein the ultrafine wire is a microwire or a nanowire.

18. The method of fabricating a wiring of a three-dimensional ultrafine conducting polymer wire having a high aspect ratio according to claim 11, wherein, in each of the steps (a), (b), (c) (d) and (e), the micropipette is adjusted on the micrometer scale by a stepping motor.

19. The method of fabricating a wiring of a three-dimensional ultrafine conducting polymer wire having a high aspect ratio according to claim 11, wherein 2-naphthalenesulfonic acid (2-NSA) is added to the aqueous monomer solution to adjust the electroconductivity of the aqueous monomer solution.

20. A wiring of three-dimensional ultrafine conducting polymer wire having a high aspect ratio, fabricated by the method of claim 11, wherein the ultrafine wire is fabricated and aligned at the same time.
